(19) United States
(12) Patent Application Publication
(10) Pub. No.: US 2025/0143158 A1
(43) Pub. Date: May 1, 2025

(54) DISPLAY DEVICE AND WEARABLE ELECTRONIC DEVICE

(71) Applicant: Samsung Display Co., LTD., Yongin-si (KR)

(72) Inventors: Jin Yeong KIM, Yongin-si (KR); Hye In JEONG, Yongin-si (KR); Sung Jin LEE, Yongin-si (KR); Jae Jin LEE, Yongin-si (KR); Jong Kuk JU, Yongin-si (KR)

(73) Assignee: Samsung Display Co., LTD., Yongin-si (KR)

(21) Appl. No.: 18/928,831

(22) Filed: Oct. 28, 2024

(30) Foreign Application Priority Data
Oct. 31, 2023 (KR) 10-2023-0148082

(51) Int. Cl. H10K 59/88; H10K 59/122; H10K 59/80

(52) U.S. Cl. CPC H10K 59/88; H10K 59/122; H10K 59/80515; H10K 59/80521

(57) ABSTRACT

A light emitting element layer of a display device is disposed on a base layer. A first light emitting part of the light emitting element layer includes first organic patterns emitting light, a charge generation layer is disposed on the first light emitting part, and a second light emitting part is disposed on the charge generation layer. The second light emitting part covers the charge generation layer in a plan view. The second light emitting part includes second organic patterns disposed in a display area and emitting light and dummy patterns disposed in a non-display area.

### CROSS-REFERENCE TO RELATED APPLICATION(S)

This application claims priority to and benefits of Korean Patent Application No. 10-2023-0148082 under 35 U.S.C. § 119 filed on Oct. 31, 2023 in the Korean Intellectual Property Office, the entire contents of which are incorporated herein by reference.

### BACKGROUND

### 1. Technical Field

An embodiment relates to a display device and a wearable electronic device.

### 2. Description of the Related Art

An organic light emitting diode (OLED) is an active light emitting display device that has an advantage of not only having a wide viewing angle and excellent contrast, but also being able to be driven at a low voltage, being lightweight and thin, and having a fast response speed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device and a wearable electronic device having improved reliability.

The objects of the disclosure are not limited to those described above, and other objects will be clearly understood by those skilled in the art from the description below.

According to embodiments, a display device may include a display area and a non-display area; a base layer and a light emitting element layer disposed on the base layer. The light emitting element layer may include a first light emitting part including first organic patterns emitting light; a charge generation layer disposed on the first light emitting part; and a second light emitting part disposed on the charge generation layer. The second light emitting part covers the charge generation layer in a plan view. The second light emitting part may include second organic patterns disposed in the display area, the second organic patterns emitting light and dummy patterns disposed in the non-display area.

Of a shortest path from the display area to an edge of the base layer, the charge generation layer may expand by about 50 μm or more from an edge of the display area to the non-display area in a plan view.

Of the shortest path from the display area to the edge of the base layer, the second light emitting part may expand by less than about 200 μm toward the edge of the base layer than the charge generation layer in a plan view.

An average size of the dummy patterns may be greater than or equal to an average size of the second organic patterns.

The dummy patterns may partially overlap each other and may completely cover the charge generation layer in the non-display area in a plan view.

The second organic patterns and the dummy patterns may have a same stack structure.

The dummy patterns and the second organic patterns may have different stack structures.

The second organic patterns may include a hole transport layer and a light emitting layer disposed on the hole transport layer, and the dummy patterns include the hole transport layer or the light emitting layer.

The display device may further include a cathode electrode disposed on the light emitting element layer, the cathode electrode may cover the second light emitting part, and the charge generation layer and the cathode electrode may be separated by the second light emitting part.

The light emitting element layer may further include anode electrodes disposed on the base layer, and a pixel defining layer covering the base layer and the anode electrode, the pixel defining layer may include openings exposing the anode electrodes in the display area, the openings may not be disposed in the non-display area, and the first light emitting part may be disposed on the pixel defining layer and may be electrically connected to anode electrodes through the openings.

Organic patterns overlapping each other in a plan view among the first organic patterns and the second organic patterns may emit light of a same color.

According to embodiments, a display device may include a display area and a non-display area; a base layer; and a light emitting element layer disposed on the base layer. The light emitting clement layer may include a first light emitting part emitting light; a charge generation layer disposed on the first light emitting part; and a second light emitting part disposed on the charge generation layer and emitting light. A thickness of each of the first light emitting part, the charge generation layer, and the second light emitting part becomes thinner as a distance from the display area increases in the non-display area. Each of the first light emitting part and the second light emitting part covers the charge generation layer in a plan view.

Of a shortest path from the display area to an edge of the base layer, the charge generation layer may expand by about 50% or less from an edge of the display area than the first light emitting part or the second light emitting part in a plan view.

Of the shortest path from the display area to the edge of the base layer, each of the first light emitting part and the second light emitting part may further expand in a range of about 100 μm to about 500 μm from the edge of the display area in a plan view.

A decrease rate of a thickness of the charge generation layer according to a distance from an edge of the display area may be greater than a decrease rate of a thickness of the first light emitting part.

Each of the first light emitting part and the second light emitting part may include organic patterns emitting light, and the organic patterns may be disposed in the display area and may not be disposed in the non-display area.

The charge generation layer may include a first charge generation layer and a second charge generation layer sequentially stacked between the first light emitting part and the second light emitting part, and the second charge generation layer may be disposed inside of the first charge generation layer.

A decrease rate of a thickness of the second charge generation layer according to a distance from an edge of the display area may be greater than a decrease rate of a thickness of the first charge generation layer.

The display device may further include a cathode electrode disposed on the light emitting element layer, the cathode electrode may cover the second light emitting part, and the charge generation layer and the cathode electrode may be separated by the second light emitting part.

According to embodiments, a wearable electronic device may include a display panel emitting light; and at least one lens disposed on the display panel. The display panel may include a display area and a non-display area; a base layer; and a light emitting element layer disposed on the base layer. The light emitting element layer may include a first light emitting part including first organic patterns emitting light; a charge generation layer disposed on the first light emitting part; and a second light emitting part disposed on the charge generation layer. The second light emitting part covers the charge generation layer in a plan view. The second light emitting part may include second organic patterns disposed in the display area, the second organic patterns emitting light and dummy patterns disposed in the non-display area.

Details of other embodiments are included in the detailed description and drawings.

In the display device and the wearable electronic device according to embodiments, the second light emitting part may include the dummy patterns in the non-display area in addition to the organic patterns of the display area, and the dummy patterns may completely cover the charge generation layer in the non-display area. Therefore, in the non-display area, the cathode electrode and the charge generation layer may be separated (or physically separated) by the dummy patterns, a short circuit between the cathode electrode and the charge generation layer may be prevented, and reliability of the display device may be improved.

In the display device and the wearable electronic device according to embodiments, the thickness of each of the first light emitting part, the charge generation layer, and the second light emitting part may decrease or become thinner as the distance from the display area increases, and the decrease rate of the thickness of the charge generation layer CGL according to the distance from the edge of the display area may be greater than the decrease rate of the thickness of the second light emitting part. The second light emitting part may completely cover the charge generation layer CGL in the non-display area. Therefore, in the non-display area, the cathode electrode and the charge generation layer may be separated by the second light emitting part.

An effect according to embodiments is not limited to the above, and further various effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a block diagram illustrating an embodiment of a display device;

FIG. 2 is a block diagram illustrating an embodiment of any one of sub-pixels of FIG. 1;

FIG. 3 is a schematic diagram of an equivalent circuit of the sub-pixel of FIG. 2;

FIG. 4 is a schematic plan view illustrating an embodiment of a display panel of FIG. 1;

FIG. 5 is an exploded perspective view illustrating a portion of the display panel of FIG. 4;

FIG. 6 is a schematic plan view illustrating an embodiment of any one of pixels of FIG. 5;

FIG. 7 is a schematic cross-sectional view illustrating an embodiment of a pixel taken along line I-I′ of FIG. 6;

FIG. 8 is a schematic cross-sectional view illustrating an embodiment of the pixel taken along line I-I′ of FIG. 6;

FIG. 9 is a schematic cross-sectional view illustrating an embodiment of a light emitting structure included in the pixel of FIG. 7;

FIG. 10 is a schematic cross-sectional view illustrating an embodiment of a display panel taken along line II-II′ of FIG. 4;

FIG. 11 is a schematic plan view illustrating an embodiment of a first area of FIG. 4;

FIGS. 12A and 12B are schematic cross-sectional views illustrating an embodiment of the display panel taken along line II-II′ of FIG. 4;

FIG. 13 is a schematic cross-sectional view illustrating an embodiment of the display panel taken along line II-II′ of FIG. 4;

FIG. 14 is a schematic plan view illustrating an embodiment of the first area of FIG. 4;

FIG. 15 is a schematic cross-sectional view illustrating an embodiment of the display panel taken along line II-II′ of FIG. 4;

FIG. 16 is a diagram illustrating a deposition process;

FIG. 17 is a block diagram illustrating an embodiment of a display system;

FIG. 18 is a schematic perspective view illustrating an application example of the display system of FIG. 17; and

FIG. 19 is a diagram illustrating a head mounted display device worn by a user of FIG. 18.

### DETAILED DESCRIPTION OF THE EMBODIMENTS

Hereinafter, embodiments are described in detail with reference to the accompanying drawings. It should be noted that in the following description, portions for understanding an operation according to the disclosure are described, and descriptions of other portions may be omitted in order not to obscure the subject matter of the disclosure. The disclosure may be embodied in other forms without being limited to the embodiments described herein. However, the embodiments described herein are provided to describe in detail to implement the technical spirit of the disclosure to those skilled in the art to which the disclosure pertains.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Throughout the specification, in a case where a portion is “connected” to another portion, the case includes not only a case where the portion is “directly connected” but also a case where the portion is “indirectly connected” with another element disposed therebetween. Terms used herein are for describing embodiments and are not intended to limit the disclosure. Throughout the specification, in a case where a portion “includes”, that portion may further include another component without excluding another component unless otherwise stated.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. The device may face in other directions (for example, rotated 90 degrees or in other directions) and thus the spatially relative terms used herein are interpreted according thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

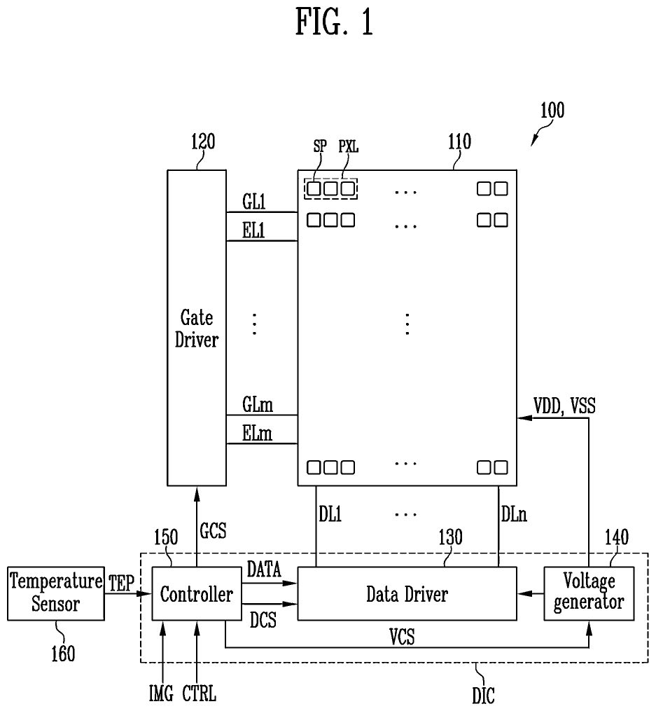

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein. FIG. 1 is a diagram illustrating an embodiment of a display device.

Referring to FIG. 1, the display device 100 may include a display panel 110 (or a display unit), a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element to generate light. Accordingly, each of the sub-pixels SP may generate light of a given color such as red, green, blue, cyan, magenta, or yellow. Two or more sub-pixels among the sub-pixels SP may form one pixel PXL. For example, as shown in FIG. 1, three sub-pixels may form one pixel PXL.

The gate driver 120 is connected to the sub-pixels SP arranged or disposed in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like within the spirit and the scope of the disclosure.

In embodiments, first to m-th emission control lines EL1 to ELm connected to the sub-pixels SP of the row direction may be further provided. The gate driver 120 may include an emission control driver to control the first to m-th emission control lines EL1 to ELm, and the emission control driver may operate under control of the controller 150.

The gate driver 120 may be disposed on one side or a side of the display panel 110. However, embodiments are not limited thereto. For example, the gate driver 120 may be divided into two or more physically and/or logically divided drivers, and such drivers may be disposed on one side or a side of the display panel 110 and another side of the display panel 110 opposite the one side. As described above, the gate driver 120 may be disposed around the display panel 110 in various shapes according to embodiments.

The data driver 130 is connected to the sub-pixels SP arranged or disposed in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start pulse, a source shift clock, a source output enable signal, and the like within the spirit and the scope of the disclosure.

The data driver 130 may apply data signals having grayscale voltages corresponding to the image data DATA to the first to n-th data lines DL1 to DLn using voltages from the voltage generator 140. In case that the gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, an image is displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 generates a plurality of voltages and provides the generated voltages to components of the display device 100. For example, the voltage generator 140 may generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than a voltage level lower of the first power voltage VDD. In other embodiments, the first power voltage VDD or the second power voltage VSS may be provided by an external device of the display device 100.

The voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a selectable reference voltage may be applied to the first to n-th data lines DL1 to DLn, and the voltage generator 140 may generate such a reference voltage.

The controller 150 controls overall operations of the display device 100. The controller 150 receives input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC.

The display device 100 may include at least one temperature sensor 160. The temperature sensor 160 may sense a temperature around the temperature sensor 160 and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

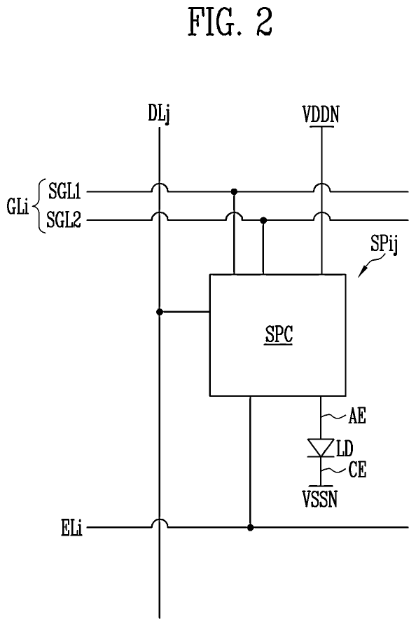

FIG. 2 is a block diagram illustrating an example of any one of the sub-pixels of FIG. 1. In FIG. 2, among the sub-pixels SP of FIG. 1, a sub-pixel SPij arranged or disposed in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. At this time, the first power voltage node VDDN is a node that transfers the first power voltage VDD of FIG. 1, and the second power voltage node VSSN is a node that transfers the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may control the light emitting element LD according to signals received through such signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, in case that the i-th gate line GLi may include two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In case that the i-th emission control line ELi may include two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light of a luminance corresponding to the data signal.

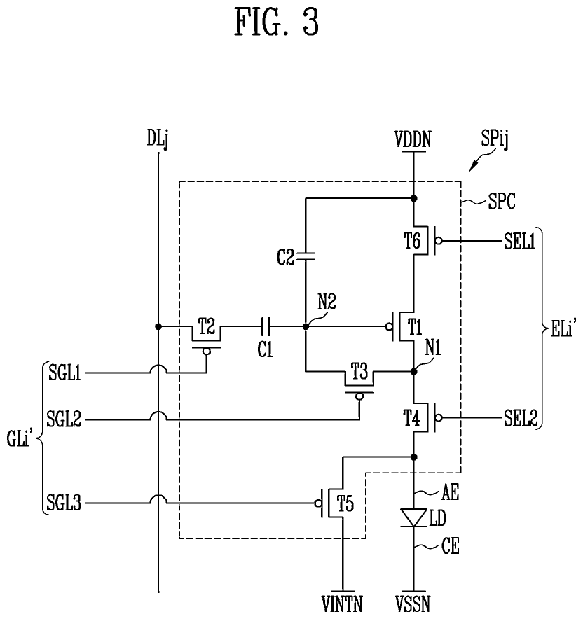

FIG. 3 is a schematic diagram of an equivalent circuit of the sub-pixel of FIG. 2.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and the j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 is connected between a first power voltage node VDDN and a first node N1. A gate of the first transistor T1 may be connected to a second node N2, and thus the first transistor T1 may be turned on according to a voltage level of the second node N2. The first transistor T1 may be referred to as a driving transistor.

The second transistor T2 is connected between the j-th data line DLj and the second node N2. A gate of the second transistor T2 may be connected to the first sub-gate line SGL1, and thus the second transistor T2 may be turned on in response to a gate signal of the first sub-gate line SGL1. The second transistor T2 may be referred to as a switching transistor.

The third transistor T3 is connected between the first node N1 and the second node N2. A gate of the third transistor T3 may be connected to the second sub-gate line SGL2, and thus the third transistor T3 may be turned on in response to a gate signal of the second sub-gate line SGL2.

The fourth transistor T4 is connected between the first node N1 and the anode electrode AE of the light emitting clement LD. A gate of the fourth transistor T4 may be connected to the second sub-emission control line SEL2, and thus the fourth transistor T4 may be turned on in response to an emission control signal of the second sub-emission control line SEL2.

The fifth transistor T5 is connected between the anode electrode AE of the light emitting clement LD and an initialization voltage node VINTN. The initialization voltage node VINTN may transfer an initialization voltage. In embodiments, the initialization voltage may be provided by voltage generator 140 of FIG. 1. In other embodiments, the initialization voltage may be provided by an external device of the display device 100. A gate of the fifth transistor T5 may be connected to the third sub-gate line SGL3, and thus the fifth transistor T5 may be turned on in response to a gate signal of the third sub-gate line SGL3.

The sixth transistor T6 is connected between the first power voltage node VDDN and the first transistor T1. A gate of the sixth transistor T6 may be connected to the first sub-emission control line SEL1, and thus the sixth transistor T6 may be turned on in response to an emission control signal of the first sub-emission control line SEL1.

The first capacitor C1 is connected between the second transistor T2 and the second node N2. The second capacitor C2 is connected between the first power voltage node VDDN and the second node N2.

As described above, the sub-pixel circuit SPC may include the first to sixth transistors T1 to T6, and the first and second capacitors C1 and C2. However, embodiments are not limited thereto. The sub-pixel circuit SPC may be implemented as any one of various types of circuits including a plurality of transistors and one or more capacitors. For example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may be variable.

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be replaced with an N-type transistor.

In embodiments, the first to sixth transistors T1 to T6 may include an amorphous silicon semiconductor, a monocrystalline silicon semiconductor, a polycrystalline silicon semiconductor, an oxide semiconductor, and the like within the spirit and the scope of the disclosure.

The light emitting element LD may include the anode electrode AE, the cathode electrode CE, and the light emitting layer. The light emitting layer may be disposed between the anode electrode AE and the cathode electrode CE. After the data signal transferred through the j-th data line DLj is reflected in a voltage of the second node N2, in case that the emission control signals of the first and second sub-emission control lines SEL1 and SEL2 are enabled to a low level, the fourth and sixth transistors T4 and T6 may be turned on. The first transistor T1 may be turned on according to the voltage of the second node N2, and thus a current may flow from the first power voltage node VDDN to the second power voltage node VSSN. The light emitting element LD may emit light according to an amount of the flowing current.

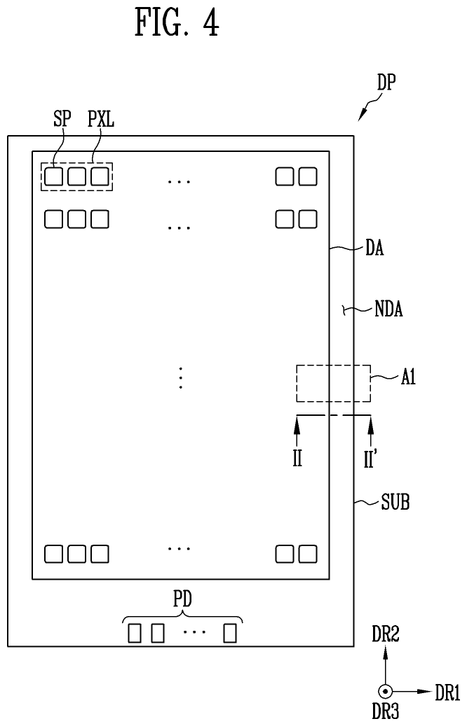

FIG. 4 is a schematic plan view illustrating an embodiment of the display panel of FIG. 1.

Referring to FIG. 4, the display panel DP may include a display area DA and a non-display area NDA. The display panel DP displays an image through the display area DA. The non-display area NDA is disposed around the display area DA.

The display panel DP may include a substrate SUB, the sub-pixels SP, and pads PD.

In case that the display panel DP is used as a display screen of a head mounted display (HMD) device, a virtual reality (VR) device, a mixed reality (MR) device, an augmented reality (AR) device, or the like, the display panel DP may be positioned very close to user's eyes. Sub-pixels SP of a relatively high integration degree are required. In order to increase an integration degree of the sub-pixels SP, the substrate SUB may be provided as a silicon substrate. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDOS) display device.

The sub-pixels SP are disposed in the display area DA on the substrate SUB. The sub-pixels SP may be arranged or disposed in a matrix shape along a first direction DR1 and a second direction DR2 intersecting the first direction DR1. However, embodiments are not limited thereto. For example, the sub-pixels SP may be arranged or disposed in a zigzag shape along the first direction DR1 and the second direction DR2. For example, the sub-pixels SP may be arranged or disposed in a PENTILE™ shape. The first direction DR1 may be a row direction, and the second direction DR2 may be a column direction.

Two or more sub-pixels among the plurality of sub-pixels SP may form one pixel PXL.

A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP and may be disposed in the non-display area NDA. In other embodiments, the gate driver 120 may be implemented as an integrated circuit separated from the display panel DP. In embodiments, the temperature sensor 160 may be disposed in the non-display area NDA to sense a temperature of the display panel DP.

The pads PD are disposed in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (refer to FIG. 1). In embodiments, voltages and signals desirable for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in case that the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive member such as an anisotropic conductive film. At this time, the circuit board may be a flexible circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight and/or curved sides. For example, the display area DA may have shapes such as a polygon, a circle, a semicircle, and an ellipse.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials having a flexible property.

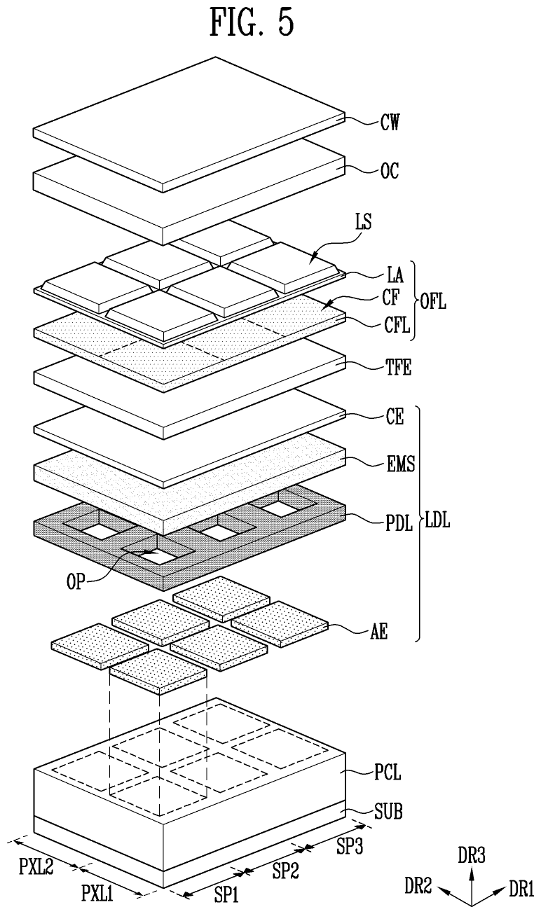

FIG. 5 is an exploded perspective view illustrating a portion of the display panel of FIG. 4. In FIG. 5, for clear and concise description, a portion of the display panel DP corresponding to two pixels PXL1 and PXL2 among the pixels PXL of FIG. 4 is schematically shown. A portion of the display panel DP corresponding to remaining pixels may be similarly configured.

Referring to FIGS. 4 and 5, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 5, the first to third sub-pixels SP1, SP2, and SP3 have quadrangle shapes when viewed from a third direction DR3 intersecting the first and second directions DR1 and DR2, and have sizes equal to each other. However, embodiments are not limited thereto. The first to third sub-pixels SP1, SP2, and SP3 may be modified to have various shapes.

The display panel DP may include the substrate SUB, a pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like within the spirit and the scope of the disclosure. In other embodiments, the substrate SUB may include a glass substrate. In other embodiments, the substrate SUB may include a polyimide (PI) substrate.

The pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least a portion of circuit elements, lines, and the like within the spirit and the scope of the disclosure. The conductive patterns may include copper, but embodiments are not limited thereto.

The circuit elements may include the sub-pixel circuit SPC (refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In embodiments, in case that the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, in case that the substrate SUB is provided as a glass substrate or a P1 substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer disposed therebetween.

The lines of the pixel circuit layer PCL may include signal lines connected to each of the first to third sub-pixels SP1, SP2, and SP3, for example, a gate line, an emission control line, a data line, and the like within the spirit and the scope of the disclosure. The lines may further include a line connected to the first power voltage node VDDN of FIG. 2. The lines may further include a line connected to the second power voltage node VSSN of FIG. 2.

The light emitting element layer LDL may include the anode electrode AE, a light emitting structure EMS, and the cathode electrode CE. According to an embodiment, the light emitting clement layer LDL may further include a pixel defining layer PDL. In other words, the pixel defining layer PDL may be omitted.

The anode electrode AE may be disposed on the pixel circuit layer PCL. The anode electrode AE may contact the circuit elements of the pixel circuit layer PCL. The anode electrode AE may include an opaque conductive material capable of reflecting light, but embodiments are not limited thereto.

The pixel defining layer PDL is disposed on the anode electrode AE. The pixel defining layer PDL may include an opening OP exposing a portion of each of the anode electrode AE. The opening OP of the pixel defining layer PDL may be understood as emission areas corresponding to the first to third sub-pixels SP1 to SP3, respectively.

In embodiments, the pixel defining layer PDL may include an inorganic material. The pixel defining layer PDL may include a plurality of stacked inorganic layers. For example, the pixel defining layer PDL may include silicon oxide SiOₓ and silicon nitride SiNₓ. In other embodiments, the pixel defining layer PDL may include an organic material. However, a material of the pixel defining layer PDL is not limited thereto.

The light emitting structure EMS may be disposed on the anode electrode AE exposed by the opening OP of the pixel defining layer PDL. The light emitting structure EMS may include a light emitting layer to generate light, an electron transport layer to transport an electron, a hole transport layer to transport a hole, and the like within the spirit and the scope of the disclosure.

In embodiments, the light emitting structure EMS may fill the opening OP of the pixel defining layer PDL, and may be entirely disposed on the pixel defining layer PDL. In other words, the light emitting structure EMS may extend across the first to third sub-pixels SP1 to SP3. At least a portion of layers in the light emitting structure EMS may be disconnected or bent at boundaries between the first to third sub-pixels SP1 to SP3. However, embodiments are not limited thereto. For example, portions of the light emitting structure EMS corresponding to the first to third sub-pixels SP1 to SP3 may be separated from each other, and each of the portions may be disposed in the opening OP of the pixel defining layer PDL.

The cathode electrode CE may be disposed on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and a mixture thereof. However, a material of the cathode electrode CE is not limited thereto.

It may be understood that any one of the anode electrode AE, a portion of the light emitting structure EMS overlapping it, and a portion of the cathode electrode CE overlapping it form one light emitting element LD (refer to FIG. 2). In other words, each of the light emitting elements of the first to third sub-pixels SP1 to SP3 may have one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and in case that the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE is disposed on the cathode electrode CE. The encapsulation layer TFE may cover the light emitting element layer LDL and/or the pixel circuit layer PCL. The encapsulation layer TFE may prevent oxygen, moisture, and/or the like from permeating to the light emitting element layer LDL. In embodiments, the encapsulation layer TFE may include a structure in which one or more inorganic layers and one or more organic layers may be alternately stacked each other. For example, the inorganic layer may include silicon nitride, silicon oxide, silicon oxynitride (SiOₓN_{y}), or the like within the spirit and the scope of the disclosure. For example, the organic layer may include an organic insulating material such as acrylic resin, epoxy resin, phenol resin, polyamides resin, polyimide resin, unsaturated polyester resin, polyphenylenether resin, polyphenylenesulfide resin, or benzocyclobutene (BCB). However, materials of the organic and the inorganic layers of the encapsulation layer TFE are not limited thereto.

In order to improve an encapsulation efficiency of the encapsulation layer TFE, the encapsulation layer TFE may further include a thin film including aluminum oxide (AlOₓ). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through atomic layer deposition (ALD) method. However, embodiments are not limited thereto. The encapsulation layer TFE may further include a thin film formed of at least one of various materials suitable for improving the encapsulation efficiency.

The optical functional layer OFL is disposed on the encapsulation layer TFE. The optical functional layer OFL may include a color filter layer CFL and a lens array LA.

The color filter layer CFL is disposed between the encapsulation layer TFE and the lens array LA. The color filter layer CFL may filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The lens array LA is disposed on the color filter layer CFL. The lens array LA may include lenses LS respectively corresponding to the first to third sub-pixels SP1 to SP3. Each of the lenses LS may improve light output efficiency by outputting the light emitted from the light emitting structure EMS to an intended path. The lens array LA may have a relatively high refractive index. For example, the lens array LA may have a refractive index higher than a refractive index of the overcoat layer OC. In embodiments, the lenses LS may include an organic material. In embodiments, the lenses LS may include an acrylic material. However, a material of the lenses LS is not limited thereto.

In embodiments, compared to the opening OP of the pixel defining layer PDL, at least a portion of the color filters CF of the color filter layer CFL and at least a portion of the lenses LS of the lens array LA may be shifted in a direction parallel to the plane defined by the first and second directions DR1 and DR2. For example, in a central area of the display area DA, a center of the color filter and a center of the lens may be aligned with or overlap a center of the opening OP of the corresponding pixel definition layer PDL when viewed in the third direction DR3. For example, in the central area of the display area DA, the opening OP of the pixel defining layer PDL may completely overlap the corresponding color filter of the color filter layer CFL and the corresponding lens of the lens array LA. In an area adjacent to the non-display area NDA in the display area DA, the center of the color filter and the center of the lens may be shifted in a plane direction from the center of the opening OP of the corresponding pixel defining layer PDL when viewed in the third direction DR3. For example, in the area adjacent to the non-display area NDA in the display area DA, the opening OP of the pixel defining layer PDL may be partially overlap of the corresponding color filter of the color filter layer CFL and the corresponding lens of the lens array LA. Accordingly, at a center of the display area DA, the light emitted from the light emitting structure EMS may be efficiently output in a normal direction of a display surface. At an outskirt of the display area DA, the light emitted from the light emitting structure EMS may be efficiently output in a direction inclined by a selectable angle with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

The cover window CW may be disposed on the overcoat layer OC. The cover window CW may protect layers thereunder. The cover window CW may have a refractive index higher than a refractive index of the overcoat layer OC. The cover window CW may include glass, but embodiments are not limited thereto. For example, the cover window CW may be an encapsulation glass to protect components disposed thereunder. In other embodiments, the cover window CW may be omitted.

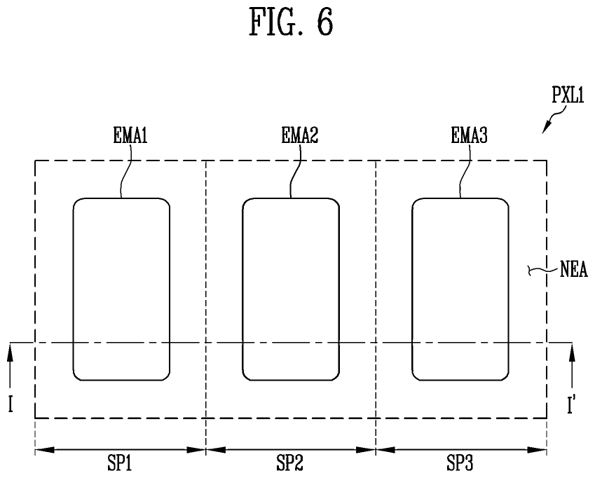

FIG. 6 is a schematic plan view illustrating an embodiment of any one of the pixels of FIG. 5. In FIG. 6, the first pixel PXL1 among the first and second pixels PXL1 and PXL2 of FIG. 5 is schematically shown for clear and concise description. The remaining pixels may be configured similarly to the first pixel PXL1.

Referring to FIGS. 5 and 6, the first pixel PXL1 may include the first to third sub-pixels SP1 to SP3 arranged or disposed in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMAl may be an area where light is emitted from a portion of the light emitting structure EMS (refer to FIG. 5) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described with reference to FIG. 5, each emission area may be understood as the opening OP of the pixel defining layer PDL corresponding to each of the first to third sub-pixels SP1 to SP3.

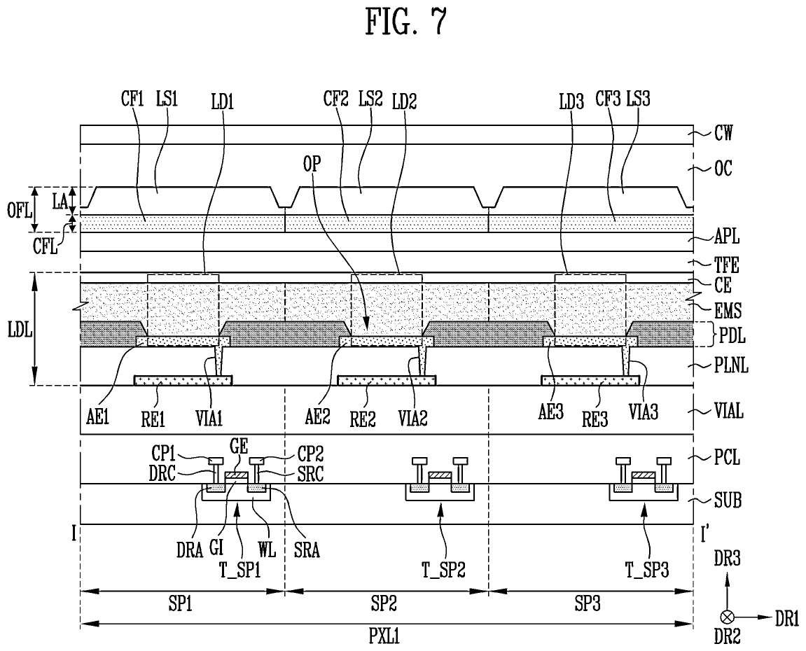

FIG. 7 is a schematic cross-sectional view illustrating an embodiment of the pixel taken along line I-I′ of FIG. 6.

Referring to FIG. 7, the substrate SUB and the pixel circuit layer PCL disposed on the substrate SUB are provided.

The substrate SUB may include a silicon wafer substrate formed using a semiconductor process. For example, the substrate SUB may include silicon, germanium, and/or silicon-germanium.

The pixel circuit layer PCL is disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1, the transistor T_SP2 of the second sub-pixel SP2 may be any one of the transistors included in the sub-pixel circuit SPC of the second sub-pixel SP2, and the transistor T_SP3 of the third sub-pixel SP3 may be any one of the transistors included in the sub-pixel circuit SPC of the third sub-pixel SP3. In FIG. 7, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be disposed in the substrate SUB. A well WL formed through an ion injection process may be disposed in the substrate SUB, and the source area SRA and the drain area DRA may be disposed to be spaced apart from each other in the well WL. An area between the source area SRA and the drain area DRA in the well WL may be defined as a channel area.

The gate electrode GE may overlap the channel area between the source area SRA and the drain area DRA and may be disposed in the pixel circuit layer PCL. The gate electrode GE may be spaced apart from the well WL or the channel area by an insulating material such as a gate insulating layer GI. The gate electrode GE may include a conductive material.

A plurality of layers included in the pixel circuit layer PCL may include insulating layers and conductive patterns disposed between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

A via layer VIAL (or a base layer) is disposed on the pixel circuit layer PCL. The via layer VIAL may cover the pixel circuit layer PCL and may have a generally flat surface. The via layer VIAL may planarize step differences on the pixel circuit layer PCL. The via layer VIAL may include at least one of silicon oxide (SiOₓ), silicon nitride (SiNₓ), and silicon carbon nitride (SiCN), but embodiments are not limited thereto.

The light emitting element layer LDL is disposed on the via layer VIAL. The light emitting clement layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 are disposed in the first to third sub-pixels SP1 to SP3, respectively. Each of the first to third reflective electrodes RE1 to RE3 may contact the circuit element disposed in the pixel circuit layer PCL through a via passing through the via layer VIAL.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them, but embodiments are not limited thereto.

In embodiments, a connection electrode may be disposed under or below each of the first to third reflective electrodes RE1 to RE3. The connection electrode may improve an electrical connection characteristic between the corresponding reflective electrode and the circuit element of the pixel circuit layer PCL. The connection electrode may have a multilayer structure. The multilayer structure may include titanium (Ti), titanium nitride (TiN), tantalum nitride (TaN), and the like, but embodiments are not limited thereto. In embodiments, a corresponding reflective electrode may be positioned between multiple layers of the connection electrodes.

In order to planarize step differences between the first to third reflective electrodes RE1 to RE3, a planarization layer PLNL may be disposed on the via layer VIAL and the first to third reflective electrodes RE1 to RE3. The planarization layer PLNL may generally cover the first to third reflective electrodes RE1 to RE3 and the via layer VIAL, and may have a flat surface. In embodiments, the planarization layer PLNL may be omitted.

The first to third anode electrodes AE1 to AE3 respectively overlapping the first to third reflective electrodes RE1 to RE3 are disposed on the planarization layer PLNL. The first to third anode electrodes AE to AE3 may have shapes similar to those of the first to third emission areas EMA1 to EMA3 of FIG. 6 when viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

In embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). However, a material of the first to third anode electrodes AE1 to AE3 is not limited thereto. For example, the first to third anode electrodes AE1 to AE3 may include titanium nitride.

The pixel defining layer PDL is disposed on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define an emission area of each of the first to third sub-pixels SP1 to SP3. As described above, the pixel defining layer PDL may be disposed in the non-emission area NEA of FIG. 6 and define the first to third emission areas EMA1 to EMA3 of FIG. 6.

The light emitting structure EMS may be disposed on the anode electrode AE exposed by the opening OP of the pixel defining layer PDL. The light emitting structure EMS may fill the opening OP of the pixel defining layer PDL and may be disposed entirely across the first to third sub-pixels SP1 to SP3. According to an embodiment, the light emitting structure EMS may be at least partially cut off in a boundary area between the first to third sub-pixels SP1 to SP3. In case that the display panel DP is operated, a current flowing out from each of the first to third sub-pixels SP1 to SP3 to a sub-pixel neighboring thereto through layers included in the light emitting structure EMS may be reduced. Therefore, first to third light emitting elements LD1 to LD3 may operate with relatively high reliability.

The cathode electrode CE may be disposed on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AEI, a portion of the light emitting structure EMS overlapping the first anode electrode AEI, and a portion of the cathode electrode CE overlapping the first anode electrode AEl may form the first light emitting element LD1. The second anode electrode AE2, a portion of the light emitting structure EMS overlapping the second anode electrode AE2, and a portion of the cathode electrode CE overlapping the second anode electrode AE2 may form the second light emitting element LD2. The third anode electrode AE3, a portion of the light emitting structure EMS overlapping the third anode electrode AE3, and a portion of the cathode electrode CE overlapping the third anode electrode AE3 may form the third light emitting element LD3.

The encapsulation layer TFE is disposed on the cathode electrode CE. The encapsulation layer TFE may prevent oxygen, moisture, and/or the like from permeating to the light emitting element layer LDL.

The optical functional layer OFL is disposed on the encapsulation layer TFE. In embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

In embodiments, the first to third color filters CF1 to CF3 may partially overlap in the boundary area BDA. In other embodiments, the first to third color filters CF1 to CF3 may be spaced apart from each other, and a black matrix may be provided between the first to third color filters CF1 to CF3.

The lens array LA is disposed on the color filter layer CFL. The lens array LA may include first to third lenses LS1 to LS3 respectively corresponding to the first to third sub-pixels SP1 to SP3. Each of the first to third lenses LS1 to LS3 may improve light output efficiency by outputting light emitted from the first to third light emitting elements LD1 to LD3 to an intended path.

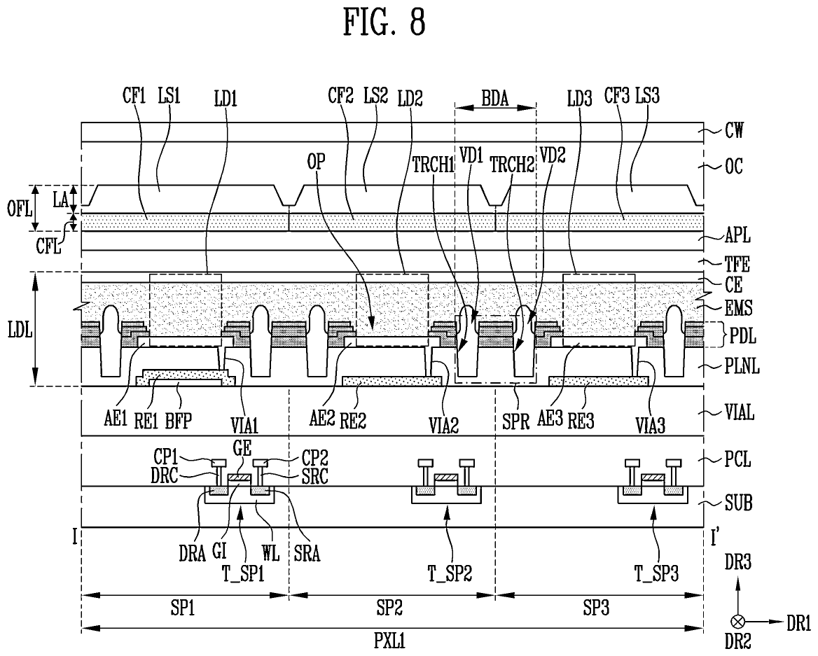

FIG. 8 is a schematic cross-sectional view illustrating an embodiment of the pixels taken along line I-I′ of FIG. 6.

Referring to FIGS. 7 and 8, except for a buffer pattern BFP and a separator SPR, the embodiment of FIG. 8 may be substantially equal or similar to the embodiment of FIG. 7. Therefore, an overlapping description may not be repeated.

The buffer pattern BFP may be disposed under or below at least one of the first to third reflective electrodes RE1 to RE3. The buffer pattern BFP may be disposed under or below at least one of the first to third reflective electrodes RE1 to RE3 in the groove of the via layer VIAL. The buffer pattern BFP may include an inorganic material such as silicon carbon nitride, but embodiments are not limited thereto. A height of the third direction DR3 of a corresponding reflective electrode may be adjusted by disposing the buffer pattern BFP. For example, the buffer pattern BFP may be disposed between the first reflective electrode REI and the via layer VIAL to adjust a height of the first reflective electrode RE1.

The first to third reflective electrodes RE1 to RE3 may function as full mirrors, and the cathode electrode CE may function as a half mirror. The light emitted from the light emitting layer of the light emitting structure EMS may be amplified by at least partially reciprocating between a corresponding reflective electrode and the cathode electrode CE, and the amplified light may be output through the cathode electrode CE. As described above a distance between each reflective electrode and the cathode electrode CE may be understood as a resonance distance for the light emitted from the light emitting layer of the corresponding light emitting structure EMS.

The first sub-pixel SP1 may have a resonance distance shorter than a resonance distance of another sub-pixel due to the buffer pattern BFP. The resonance distance adjusted as described above may allow light of a given wavelength range (for example, red color) to be effectively and efficiently amplified. Accordingly, the first sub-pixel SP1 may effectively and efficiently output light of a corresponding wavelength range.

In FIG. 8, the buffer pattern BFP is provided to the first sub-pixel SP1 and is not provided to the second and third sub-pixels SP2 and SP3, but embodiments are not limited thereto. The buffer pattern may also be provided to at least one of the second and third sub-pixels SP2 and SP3 to adjust the resonance distance of at least one of the second and third sub-pixels SP2 and SP3. For example, the first to third sub-pixels SP1 to SP3 may correspond to red, green, and blue, respectively, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In embodiments, insulating layers for adjusting a height of one or more of the first to third anode electrodes AE1 to AE3 may be further provided. The insulating layers may be disposed between one or more of the first to third anode electrodes AE1 to AE3 and the corresponding reflective electrodes. The planarization layer PLNL and/or the buffer pattern BFP may be omitted. For example, the first to third sub-pixels SP1 to SP3 may correspond to red, green, and blue, respectively, a distance between the first anode electrode AEl and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE.

The pixel defining layer PDL may include a plurality of inorganic insulating layers. Each of the plurality of inorganic insulating layers may include at least one of silicon oxide (SiOₓ) and silicon nitride (SiNₓ). For example, the pixel defining layer PDL may include sequentially stacked first to third inorganic insulating layers, and the first to third inorganic insulating layers may include silicon nitride, silicon oxide, and silicon nitride, respectively. However, embodiments are not limited thereto. The first to third inorganic insulating layers may have a cross-section of a step shape in an area adjacent to the opening OP.

The separator SPR may be provided in a boundary area BDA between neighboring sub-pixels. In other words, the separator SPR may be provided in each of boundary areas between the sub-pixels SP of FIG. 4.

The separator SPR may cause formation of a discontinuity in the light emitting structure EMS at the boundary area BDA. For example, the light emitting structure EMS may be disconnected or bent at the boundary area BDA due to the separator SPR.

The separator SPR may be provided in or on the pixel defining layer PDL. The pixel defining layer PDL may include one or more trenches TRCH1 and TRCH2 as the separator SPR in the boundary area BDA. In embodiments, as shown in FIG. 8, the one or more trenches TRCH1 and TRCH2 may pass through the pixel defining layer PDL and may partially pass through the planarization layer. In other embodiments, the one or more trenches TRCH1 and TRCH2 may pass through the pixel defining layer PDL and the planarization layer PLNL and may partially pass through the via layer VIAL. In other embodiments, the one or more trenches TRCH1 and TRCH2 may at least partially pass through the planarization layer PLNL and the via layer VIAL, and a portion of the pixel defining layer PDL may be disposed in the one or more trenches TRCH1 and TRCH2.

For example, two trenches TRCH1 and TRCH2 separated from each other may be provided in the boundary area BDA. For example, the first trench TRCH1 and the second trench TRCH2 may be disposed in the boundary area BDA between the second sub-pixel SP2 and the third sub-pixel SP3, the first trench TRCH1 may be disposed along an edge of the second sub-pixel SP2, and the second trench TRCH2 may be disposed along an edge of the third sub-pixel SP3. In case that the trenches TRCH1 and TRCH2 are separated from each other, a width of each of the trenches TRCH1 and TRCH2 may be maintained constant, and the discontinuous portion of the light emitting structure EMS may exist uniformly in the boundary area BDA. In case that the trenches TRCH1 and TRCH2 are connected, a width of a connection portion of the trenches TRCH1 and TRCH2 may become larger than a width of another portion, the discontinuous portion of the light emitting structure EMS may become uneven, and a characteristic of the light emitting structure EMS may become uneven.

In FIG. 8, the two trenches TRCH1 and TRCH2 are provided in the boundary area BDA. However, embodiments are not limited thereto. For example, the pixel defining layer PDL may include one trench in the boundary area BDA. By way of example, the pixel defining layer PDL may include three or more trenches in the boundary area BDA.

Due to the first and second trenches TRCH1 and TRCH2, in the boundary area BDA, discontinuous portions such as a first void VD1 and a second void VD2 may be formed in the light emitting structure EMS. A portion of a plurality of layers stacked in the light emitting structure EMS may be disconnected or bent by the first and second voids VD1 and VD2. For example, at least one charge generation layer included in the light emitting structure EMS may be disconnected in the first and second voids VD1 and VD2. As described above, portions of the light emitting structure EMS included in the first to third sub-pixels SP1 to SP3 may be at least partially separated due to the first and second trenches TRCH1 and TRCH2.

In FIG. 8, in the boundary area BDA, the first and second voids VD1 and VD2 are formed in the light emitting structure EMS, but this is an example, and embodiments are not limited thereto. For example, in the boundary area BDA, a valley of a concave shape may be formed in the light emitting structure EMS. According to shapes of the first and second trenches TRCH1 and TRCH2, discontinuous portions formed in the light emitting structure EMS may be variously changed.

In embodiments, the light emitting structure EMS may be formed through a process of vacuum deposition, inkjet printing, and the like within the spirit and the scope of the disclosure. The same materials as the light emitting structure EMS may be positioned on bottom surfaces of the first and second trenches TRCH1 and TRCH2 adjacent to the via layer VIAL.

The separator may be variously modified and provided so that the light emitting structure EMS may have a discontinuous portion in the boundary area BDA. In embodiments, inorganic insulating patterns additionally stacked each other on the pixel defining layer PDL may be provided in the boundary area BDA without the first and second trenches TRCH1 and TRCH2. A width of the uppermost inorganic insulating pattern among the additionally stacked inorganic insulating patterns may be greater than a width of the inorganic insulating pattern disposed immediately thereunder. For example, in the boundary area BDA, first to third inorganic insulating patterns may be sequentially stacked from the pixel defining layer PDL, and the uppermost third inorganic insulating pattern may have a width greater than a width of the second inorganic insulating pattern. For example, the pixel defining layer PDL may have a cross-section of a “T” shape or an “I” shape in the boundary area BDA. According to a shape of the pixel defining layer PDL, a plurality of layers included in the light emitting structure EMS may be at least partially disconnected or bent in the boundary area BDA.

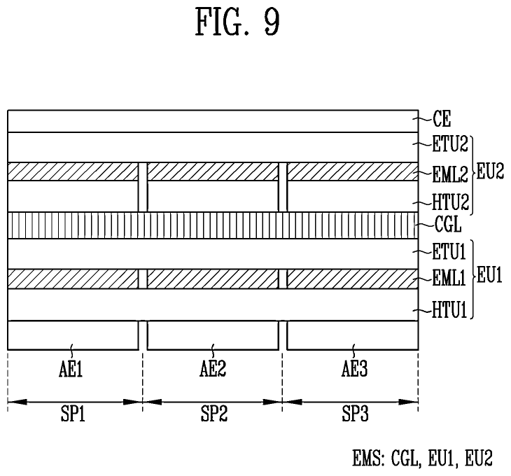

FIG. 9 is a schematic cross-sectional view illustrating an embodiment of the light emitting structure included in the pixel of FIG. 7. For convenience of description, FIG. 9 further shows the first and third anode electrodes AE1 to AE3 and the cathode electrode CE.

Referring to FIG. 9, the light emitting structure EMS may have a tandem structure in which first and second light emitting units (or parts) EU1 and EU2 are stacked. The light emitting structure EMS may be configured substantially equally or similarly in each of the first to third sub-pixels SP1 to SP3.

Each of the first and second light emitting units EU1 and EU2 may include at least one light emitting layer that generates light according to an applied current. The first light emitting unit EU1 may include a first light emitting layer EML1, a first electron transport unit ETUI, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer, and may further include a hole buffer layer, an electron blocking layer, and the like if desirable. The first and second hole transport units HTU1 and HTU2 may have configurations equal to each other or different from each other. The first and second hole transport units HTU1 and HTU2 may be formed through a deposition process, but are not limited thereto

Each of the first and second electron transport units ETU1 and ETU2 may include at least one of an electron injection layer and an electron transport layer, and may further include an electron buffer layer, a hole blocking layer, and the like if desirable. The first and second electron transport units ETU1 and ETU2 may have configurations equal to each other or different from each other. The first and second electron transport units ETU1 and ETU2 may be formed through a deposition process, but are not limited thereto

A connection layer, which may be provided in a form of a charge generation layer CGL, may be disposed between the first light emitting unit EU1 and the second light emitting unit EU2 to connect the first light emitting unit EU1 and the second light emitting unit EU2 to each other. The charge generation layer CGL may be formed through a deposition process, but is not limited thereto. In embodiments, the charge generation layer CGL may have a stack structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide metal, or a combination thereof. However, embodiments are not limited thereto.

In embodiments, the first light emitting layer EML1 and the second light emitting layer EML2 may generate light of the same color. For example, in the first sub-pixel SP1, each of the first light emitting layer EML1 and the second light emitting layer EML2 may generate light of a red color. In the second sub-pixel SP2, each of the first light emitting layer EML1 and the second light emitting layer EML2 may generate light of a green color. In the third sub-pixel SP3, each of the first light emitting layer EML1 and the second light emitting layer EML2 may generate light of a blue color.

In an embodiment, the first light emitting layer EML1 and the second light emitting layer EML2 may generate light of different colors. Light emitted from each of the first light emitting layer EML1 and the second light emitting layer EML2 may be mixed and viewed as white light. For example, the first light emitting layer EML1 may generate light of a blue color, and the second light emitting layer EML2 may generate light of a yellow color. In embodiments, the second light emitting layer EML2 may include a structure in which a first sub light emitting layer to generate light of a red color and a second sub light emitting layer to generate light of a green color may be stacked each other. The light of the red color and the light of the green color may be mixed, and thus the light of the yellow color may be provided. An intermediate layer may perform a function of transporting holes and/or blocking transport of electrons may be further disposed between the first and second sub light emitting layers.

The first light emitting layer EML1 and the second light emitting layer EML2 may be formed through an inkjet printing method, but embodiments are not limited thereto.

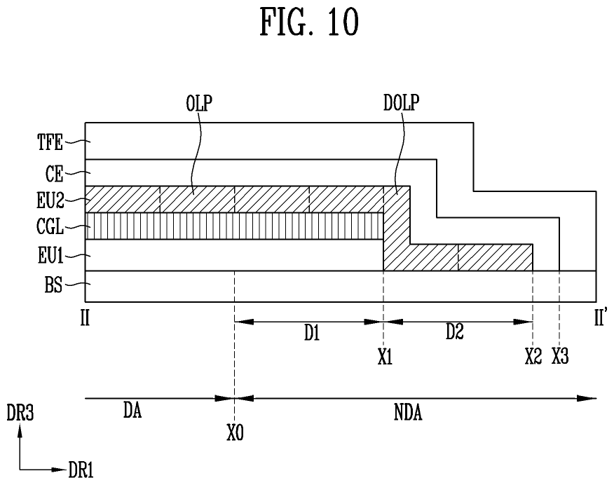

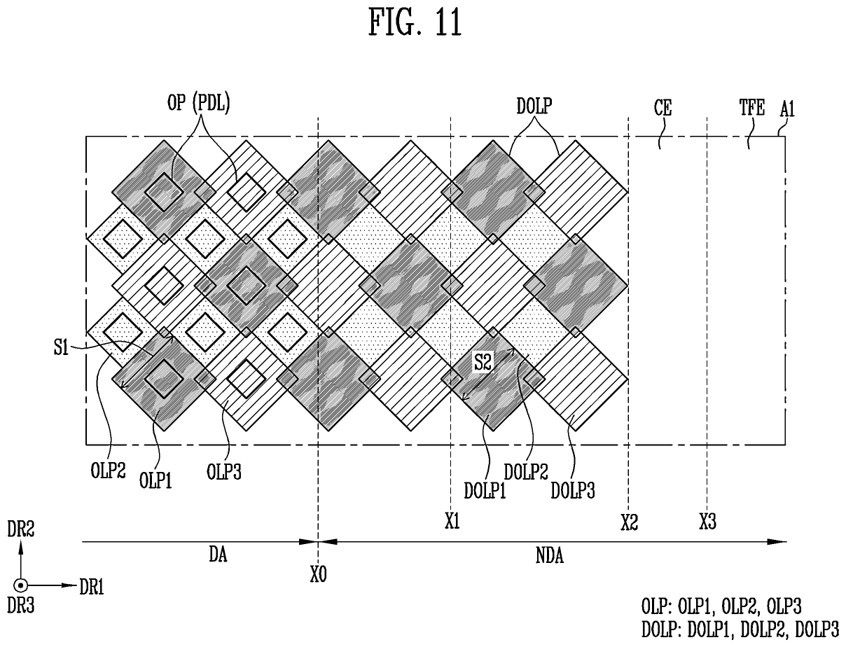

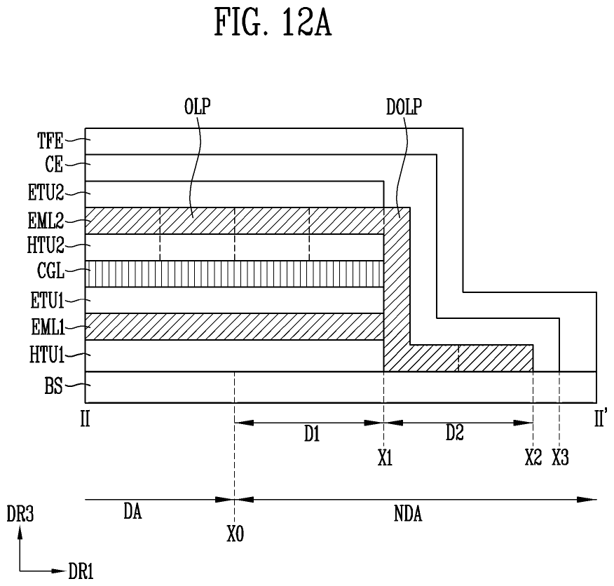

FIG. 10 is a schematic cross-sectional view illustrating an embodiment of the display panel taken along line II-II′ of FIG. 4. For convenience of description, only a partial configuration of the display panel is shown in FIG. 10, and configurations according to the embodiments of FIGS. 7 and 8 may be applied to FIG. 10. FIG. 11 is a schematic plan view illustrating an embodiment of a first area of FIG. 4. The embodiment of FIG. 11 may be applied not only to the first area Al positioned on a right side of the display panel DP but also to other sides (for example, areas of an upper side and a left side). FIGS. 12A and 12B are schematic cross-sectional views illustrating an embodiment of the display panel taken along line II-II′ of FIG. 4.

Referring to FIGS. 10 and 11, a base layer BS may include the display area DA and the non-display area NDA. The base layer BS may be the via layer VIAL of FIG. 7, but is not limited thereto. For example, the base layer BS may be the substrate SUB of FIG. 7.

The light emitting element layer (or the light emitting structure) is disposed on the base layer BS. The light emitting element layer may include the first light emitting unit EU1, the charge generation layer CGL, and the second light emitting unit EU2.

The first light emitting unit EU1 is disposed on the base layer BS. The first light emitting unit EU1 may include organic patterns OLP (or a patterned organic layer) emitting light. Each of the organic patterns OLP (or first organic patterns) of the first light emitting unit EU1 may include the first light emitting layer EML1, the first electron transport unit ETU1, and the first hole transport unit HTU1 of FIG. 9.

The organic patterns OLP of the first light emitting unit EU1 may generate light of different colors. For example, the first organic pattern OLP1 may generate light of a red color, the second organic pattern OLP2 may generate light of a green color, and the third organic pattern OLP3 may generate light of a blue color. However, embodiments are not limited thereto. The organic patterns OLP of the first light emitting unit EU1 may be formed through an inkjet printing method using a fine metal mask, but is not limited thereto.

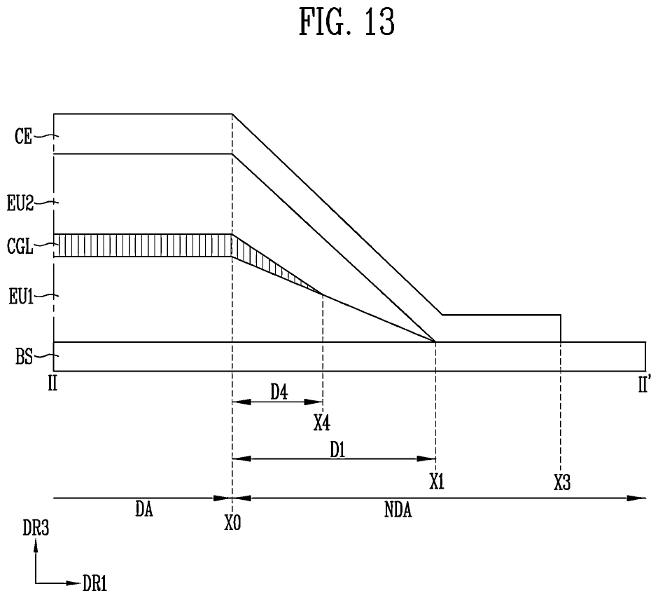

The first light emitting unit EU1 may be disposed in the display area DA (refer to FIG. 14). According to an embodiment, the first light emitting unit EU1 may be further disposed in a portion of the non-display area NDA adjacent to an edge of the display area DA.

As described with reference to FIG. 7, the first to third anode electrodes AEl to AE3 may be disposed on the base layer BS (or the via layer VIAL), and the pixel defining layer PDL may cover the base layer BS and the first to third anode electrodes AE1 to AE3. As shown in FIG. 11, an opening OP exposing the first to third anode electrodes AEl to AE3 may be formed in the pixel defining layer PDL in the display area DA. The first light emitting unit EU1 may be disposed on the pixel defining layer PDL and may contact or may be connected to the first to third anode electrodes AEl to AE3 through the opening OP. Therefore, the first light emitting unit EU1 may emit light normally in the display area DA. The opening OP of the pixel defining layer PDL is not formed in the non-display area NDA, and thus even though the first light emitting unit EU1 is disposed in the non-display area NDA, the first light emitting unit EU1 of the non-display area NDA does not emit light.

The charge generation layer CGL is disposed on the first light emitting unit EU1.

In an embodiment, the charge generation layer CGL may also be disposed in the non-display area NDA. For example, with reference to FIG. 10, the charge generation layer CGL may be formed up to a first point X1 positioned further outside a reference point X0, which is the edge of the display area DA. For example, a distance D1 between the reference point X0 and the first point X1 may be about 50 μm or more. In other words, based on the shortest path from the display area DA to an edge of the base layer BS in a plan view, the charge generation layer CGL may expand by about 50 μm or more from the edge of the display area DA to the non-display area NDA (for example, X1>X0+50 μm).

In FIG. 10, an end of the charge generation layer CGL and an end of the first light emitting unit EU1 are aligned, but the disclosure is not limited thereto. For example, the end of the charge generation layer CGL and the end of the first light emitting unit EU1 may not be aligned, and the end of the charge generation layer CGL may be positioned outside or inside compared to the end of the first light emitting unit EU1.

The second light emitting unit EU2 is disposed on the charge generation layer CGL.

In an embodiment, the second light emitting unit EU2 may cover the charge generation layer CGL. For example, with reference to FIG. 10, the second light emitting unit EU2 may be formed up to a second point X2 positioned further outside the first point X1. For example, a distance D2 between the first point X1 and the second point X2 may be about 200 μm or less. In other words, based on the shortest path from the display area DA to the edge of the base layer BS in a plan view, the second light emitting unit EU2 may expand than the charge generation layer CGL and may expand by less than about 200 μm towards the edge of the base layer BS (X1<X2<X1+200 μm).

In an embodiment, the second light emitting unit EU2 may include organic patterns OLP (or a patterned organic layer) and dummy patterns DOLP (or dummy organic patterns).

The organic patterns OLP (or second organic patterns) of the second light emitting unit EU2 may be positioned in the display area DA and may emit light. Each of the organic patterns OLP of the second light emitting unit EU2 may include the second light emitting layer EML2, the second electron transport unit ETU2, and the second hole transport unit HTU2 of FIG. 9.

The organic patterns OLP of the second light emitting unit EU2 may generate light of different colors.

According to an embodiment, organic patterns OLP overlapping each other among the organic patterns OLP (or the second organic patterns) of the second light emitting unit EU2 and the organic patterns OLP (or the first organic patterns) of the first light emitting unit EU1 may emit light of the same color. For example, a first organic pattern OLP1 of the second light emitting unit EU2 may generate light of a red color, a second organic pattern OLP2 of the second light emitting unit EU2 may generate light of a green color, and a third organic pattern OLP3 of the second light emitting unit EU2 may generate light of a blue color. However, embodiments are not limited thereto. The organic patterns OLP of the second light emitting unit EU2 may be formed through an inkjet printing method using a fine metal mask (FMM), but are not limited thereto.

The dummy patterns DOLP may be positioned in the non-display area NDA. The dummy patterns DOLP may have a structure and a size corresponding to the organic patterns OLP of the second light emitting unit EU2.

In an embodiment, at least a portion of the dummy patterns DOLP may have the same stack structure as the organic patterns OLP of the second light emitting unit EU2. For example, the dummy patterns DOLP may include the second light emitting layer EML2, the second electron transport unit ETU2, and the second hole transport unit HTU2 of FIG. 9. For example, a first dummy pattern DOLP1 may have the same stack structure as the first organic pattern OLP1, a second dummy pattern DOLP2 may have the same stack structure as the second organic pattern OLP2, and a third dummy pattern DOLP3 may have the same stack structure as the third organic pattern OLP3. However, the disclosure is not limited thereto.

In an embodiment, at least a portion of the dummy patterns DOLP may have a stack structure different from a stack structure of the organic patterns OLP of the second light emitting unit EU2. For example, the organic patterns OLP of the second light emitting unit EU2 may include the second light emitting layer EML2, the second electron transport unit ETU2, and the second hole transport unit HTU2 of FIG. 9, and at least a portion of the dummy patterns DOLP may include only a portion of the second light emitting layer EML2, the second electron transport unit ETU2, and the second hole transport unit HTU2.

For example, as shown in FIG. 12A, at least a portion of the dummy patterns DOLP may include only the second light emitting layer EML2. As an embodiment, as shown in FIG. 12B, at least a portion of the dummy patterns DOLP may include only the second hole transport unit HTU2 (or a hole transport layer). In FIGS. 12A and 12B, between the reference point X0 and the first point X1, the dummy patterns DOLP have the same stack structure as the organic patterns OLP of the second light emitting unit EU2, but are not limited thereto. For example, in FIGS. 12A and 12B, between the reference point X0 and the first point X1, the dummy patterns DOLP may include only the second light emitting layer EML2 or the second hole transport unit HTU2.

The dummy patterns DOLP may be formed through the same process as the organic patterns OLP of the second light emitting unit EU2. For example, the dummy patterns DOLP may be formed through an inkjet printing method using an FMM, but are not limited thereto.

In an embodiment, an average size of the dummy patterns DOLP may be greater than or equal to an average size of the organic patterns OLP of the second light emitting unit EU2. In a plan view, dummy patterns DOLP adjacent to each other may partially overlap each other and may completely cover the charge generation layer CGL in the non-display area NDA.

For example, a width S2 of the first dummy pattern DOLP1 may be equal to a width S1 of the first organic pattern OLP1. As an embodiment, the width S2 of the first dummy pattern DOLP1 may be greater than the width S1 of the first organic pattern OLP1. Similarly, a width of the second dummy pattern DOLP2 may be greater than or equal to a width of the second organic pattern OLP2, and a width of the third dummy pattern DOLP3 may be greater than or equal to a width of the third organic pattern OLP3.

For reference, adjacent organic patterns OLP among the first organic pattern OLP1, the second organic pattern OLP2, and the third organic pattern OLP3 may or may not partially overlap each other. Due to a process error, the adjacent organic patterns OLP among the first organic pattern OLP1, the second organic pattern OLP2, and the third organic pattern OLP3 may not overlap and may be spaced apart from each other. The dummy patterns DOLP may be required to overlap each other in order to completely cover the charge generation layer CGL. To this end, the average size of the dummy patterns DOLP may be greater than the average size of the organic patterns OLP.

The cathode electrode CE is disposed on the second light emitting unit EU2. The cathode electrode CE may cover the second light emitting unit EU2. For example, with reference to FIG. 10, the cathode electrode CE may be formed up to a third point X3 positioned further outside the second point X2.

In the non-display area NDA, the cathode electrode CE and the charge generation layer CGL may be separated (or physically separated) by the second light emitting unit EU2 (or the dummy patterns DOLP). Since the charge generation layer CGL is completely covered by the second light emitting unit EU2, the cathode electrode CE and the charge generation layer CGL may be spaced apart from each other. Therefore, a short circuit between the cathode electrode CE and the charge generation layer CGL may be prevented.

For reference, in case that the second light emitting unit EU2 does not cover the charge generation layer CGL, the end of the charge generation layer CGL may be exposed in the non-display area NDA, and the end of the charge generation layer CGL may contact the cathode electrode CE. A drop (for example, a voltage drop) may occur in a power voltage applied to the cathode electrode CE, and reliability of the display device may be reduced. In order to prevent this, the charge generation layer CGL may be positioned inside compared to the first light emitting unit EU1 and the second light emitting unit EU2, but the display area DA may be decreased and the non-display area NDA (or a dead space) may be increased by a product specification (for example, the distance D1). In consideration of this, only the second light emitting unit EU2 according to embodiments may be expanded to cover the charge generation layer CGL, and the second light emitting unit EU2 may prevent a short circuit between the charge generating layer CGL and the cathode electrode CE and may minimize the increase of the non-display area NDA.

An encapsulation layer TFE is disposed on the cathode electrode CE. The encapsulation layer TFE may cover the cathode electrode CE.

As described above, the second light emitting unit EU2 may include the dummy patterns DOLP in the non-display area NDA in addition to the organic patterns OLP of the display area DA, and the dummy patterns DOLP may completely cover the charge generation layer CGL in the non-display area NDA. Therefore, in the non-display area NDA, the cathode electrode CE and the charge generation layer CGL may be separated (or physically separated) by the dummy patterns DOLP, a short circuit between the cathode electrode CE and the charge generation layer CGL may be prevented, and reliability of the display device may be improved.

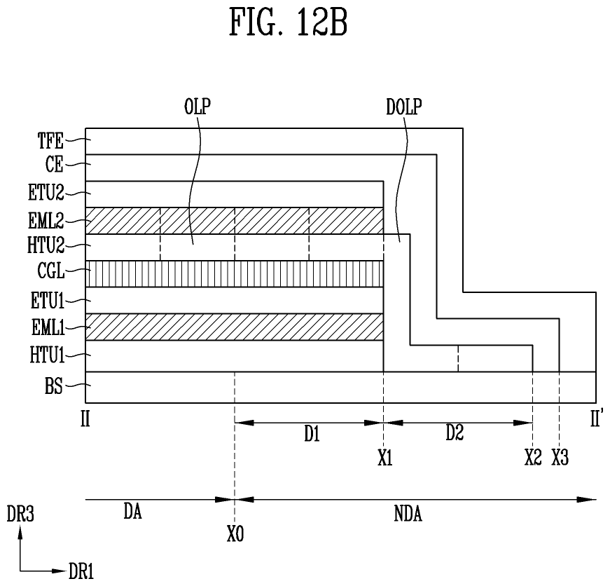

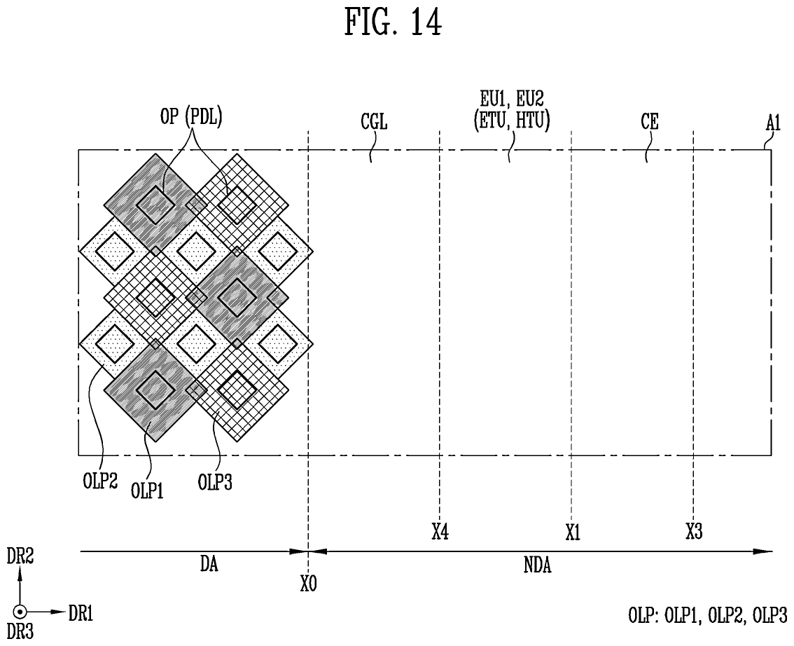

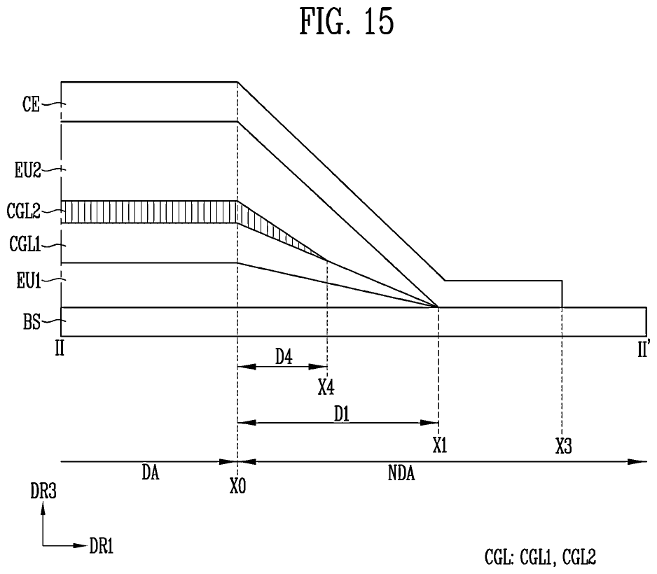

FIG. 13 is a schematic cross-sectional view illustrating an embodiment of the display panel taken along line II-II′ of FIG. 4. For convenience of description, only a partial configuration of the display panel is shown in FIG. 13, and configurations according to the embodiments of FIGS. 7 and 8 may be applied to FIG. 13. FIG. 14 is a schematic plan view illustrating an embodiment of the first area of FIG. 4. The embodiment of FIG. 14 may be applied not only to the first area Al positioned on a right side of the display panel DP but also to other sides (for example, areas of an upper side and a left side). FIG. 15 is a schematic cross-sectional view illustrating an embodiment of the display panel taken along line II-II′ of FIG. 4. FIG. 16 is a diagram illustrating a deposition process.

Referring to FIGS. 13 and 14, the light emitting element layer (or the light emitting structure) is disposed on the base layer BS. The light emitting element layer may include the first light emitting unit EU1, the charge generation layer CGL, and the second light emitting unit EU2.

The first light emitting unit EU1 is disposed on the base layer BS. The first light emitting unit EU1 may also be disposed in the non-display area NDA. For example, with reference to FIG. 13, the first light emitting unit EU1 may be formed up to the first point X1 positioned further outside the reference point X0, which is the edge of the display area DA.

The first light emitting unit EU1 may include the first light emitting layer EML1 of FIG. 9, the first electron transport unit ETU1 (or the electron transport unit ETU), and the first hole transport unit HTU1 (or the hole transport unit HTU), and the first light emitting layer EML1 may be disposed only in the display area DA. As described with reference to FIG. 11, the opening OP may be formed in the pixel defining layer PDL in the display area DA, and the organic patterns OLP (or the first to third organic patterns OLP1 to OLP3) of the first light emitting layer EML1 may contact or may be connected to a lower configuration (for example, the anode electrode) through the opening OP. The first light emitting layer EML1 (or the organic patterns OLP) is not disposed in the non-display area NDA. However, the disclosure is not limited thereto.

In the non-display area NDA, a thickness of the first light emitting unit EU1 may decrease or become thinner as a distance from the display area DA increases.

For example, the first hole transport unit HTU1 (and the electron transport unit ETU1) of the first light emitting unit EU1 may be formed through a deposition process using a mask MASK of FIG. 16 (or an open mask).

The mask MASK may include an opening corresponding to the display area DA, and a material supplied from a deposition source SOURCE may be deposited on the display area DA to form a corresponding layer (for example, the first hole transport unit HTU). The mask MASK may include a half etching area in the non-display area NDA, and in the half etching area, the mask MASK may be spaced apart from the base layer BS by a given gap G1. For example, the mask MASK may have a reference thickness T0, and may have a thickness reduced by the given gap G1 in the half etching area.

A deposition shadow is generated by the half etching area of the mask MASK, and the corresponding layer (for example, the first hole transport unit HTU1) may also be deposited in the non-display area NDA, and a thickness of the corresponding layer (for example, the first hole transport unit HTU1) may become thinner as a distance from the opening (or the display area DA) increases. A width W_S (or a breadth) of the deposition shadow may be determined by a reference thickness T0 of the mask MASK and the gap G1 in the half etching area.

The charge generation layer CGL is disposed on the first light emitting unit EU1. The charge generation layer CGL may also be disposed in the non-display area NDA. In the non-display area NDA, a thickness of the charge generation layer CGL may decrease or become thinner as the distance from the display area DA increases. The charge generation layer CGL may be formed through the deposition process of FIG. 16.

In an embodiment, as shown in FIG. 13, the charge generation layer CGL may be formed only up to a fourth point X4 positioned further inside the first point X1. For example, by reducing the gap G1 of FIG. 16 compared to a case where the first light emitting unit EU1 is formed, the charge generation layer CGL may be formed only up to the fourth point X4. For example, a distance D4 between the reference point X0, which is the edge of the display area DA, and the fourth point X4 may be about 50% or less the distance D1 between the reference point X0 and the first point X1. For example, in the embodiment of FIG. 13, the distance D1 to the first point X1 may be about 100 μm to about 500 μm.

In other words, based on the shortest path from the display area DA to the edge of the base layer BS in a plan view, the charge generation layer CGL may expand by about 50% or less from the edge of the display area DA than the first light emitting unit EU1, and the first light emitting unit EU1 may further expand by about 100 μm to about 500 μm from the edge of the display area DA.

In an embodiment, a decrease rate of a thickness of the charge generation layer CGL according to a distance from the edge of the display area DA may be greater than a decrease rate of a thickness of the first light emitting unit EU1. Here, the decrease rate may mean a rate (for example, a decreased rate of a thickness at a given position based on a thickness of the reference point X0. For example, in case that the distance D4 between the reference point X0 and the fourth point X4 is about half the distance D1 between the reference point X0 and the first point X1, the decrease rate of the thickness of the charge generation layer CGL may be about twice the decrease rate of the thickness of the first light emitting unit EU1.

The second light emitting unit EU2 is disposed on the charge generation layer CGL. The second light emitting unit EU2 may cover the charge generation layer CGL. The second light emitting unit EU2 may completely cover the charge generation layer CGL. As shown in FIG. 14, in a plan view, each of the second light emitting unit EU2 and the first light emitting unit EU1 may cover the charge generation layer CGL. The second light emitting unit EU2 may be formed up to the first point X1. In case that each of the second light emitting unit EU2 and the first light emitting unit EU1 is formed using the same mask MASK, an end of the second light emitting unit EU2 may coincide or may be aligned with the end of the first light emitting unit EU1.

The second light emitting unit EU2 may include the second light emitting layer EML2 of FIG. 9, the second electron transport unit ETU2 (or the electron transport unit ETU), and the second hole transport unit HTU2 (or the hole transport unit HTU), and the second light emitting layer EML2 (or the organic patterns OLP of the second light emitting layer EML2) may be disposed only in the display area DA. The second light emitting layer EML2 (or the organic patterns OLP) is not disposed in the non-display area NDA. However, the disclosure is not limited thereto.

In the non-display area NDA, a thickness of the second light emitting unit EU2 may decrease or become thinner as a distance from the display area DA increases. In case that each of the second light emitting unit EU2 and the first light emitting unit EU1 is formed using the same mask MASK, the end of the second light emitting unit EU2 may coincide or may be aligned with the end of the first light emitting unit EU1. A decrease rate of the thickness of the second light emitting unit EU2 according to the distance from the edge of the display area DA may be less than the decrease rate of the thickness of the charge generation layer CGL. For example, the decrease rate of the thickness of the second light emitting unit EU2 may be substantially the same as the decrease rate of the thickness of the first light emitting unit EU1.

The cathode electrode CE is disposed on the second light emitting unit EU2. The cathode electrode CE may cover the second light emitting unit EU2. For example, the cathode electrode CE may be formed up to the third point X3 positioned further outside the second point X2.

In the non-display area NDA, the cathode electrode CE and the charge generation layer CGL may be separated (or physically separated) by the second light emitting unit EU2. Since the charge generation layer CGL is completely covered by the second light emitting unit EU2, the cathode electrode CE and the charge generation layer CGL may be spaced apart from each other. Therefore, a short circuit between the cathode electrode CE and the charge generation layer CGL may be prevented.

In an embodiment, the charge generation layer CGL may include a first charge generation layer CGL1 and a second charge generation layer CGL2 sequentially stacked between the first light emitting unit EU1 and the second light emitting unit EU2, one of the first charge generation layer CGL1 and the second charge generation layer CGL2 may be positioned inside compared to the other. For example, the first charge generation layer CGL1 may an n dopant layer including an alkali metal, an alkaline earth metal, a lanthanide metal, or a combination thereof, and the second charge generation layer CGL2 may be a p dopant layer including a p-type dopant such as HAT-CN, TCNQ, and NDP-9. For example, with reference to FIG. 15, the second charge generation layer CGL2 may be positioned inside compared to the first charge generation layer CGL1. For example, a decrease rate of a thickness of the second charge generation layer CGL2 according to the distance from the edge of the display area DA may be greater than a decrease rate of a thickness of the first charge generation layer CGL1. In the non-display area NDA, the cathode electrode CE and the second charge generation layer CGL2 may be separated (or physically separated) by the second light emitting unit EU2, and a short circuit between the cathode electrode CE and the second charge generation layer CGL2 may be prevented.

As described above, the thickness of each of the first light emitting unit EU1, the charge generation layer CGL, and the second light emitting unit EU2 may decrease or become thinner as the distance from the display area DA increases, the decrease rate of the thickness of the charge generation layer CGL according to the distance from the edge of the display area DA may be greater than the decrease rate of the thickness of the second light emitting unit EU2. The second light emitting unit EU2 may completely cover the charge generation layer CGL in the non-display area NDA. Therefore, in the non-display area NDA, the cathode electrode CE and the charge generation layer CGL may be separated (or physically separated) by the second light emitting unit EU2, a short circuit between the cathode electrode CE and the charge generation layer CGL may be prevented, and reliability of the display device may be improved.

The embodiment of FIG. 10 may be applied to the embodiment of FIGS. 13 to 15. For example, in the embodiments of FIGS. 13 to 15, the second light emitting unit EU2 may include the dummy patterns DOLP (refer to FIG. 10) disposed in the non-display area NDA.

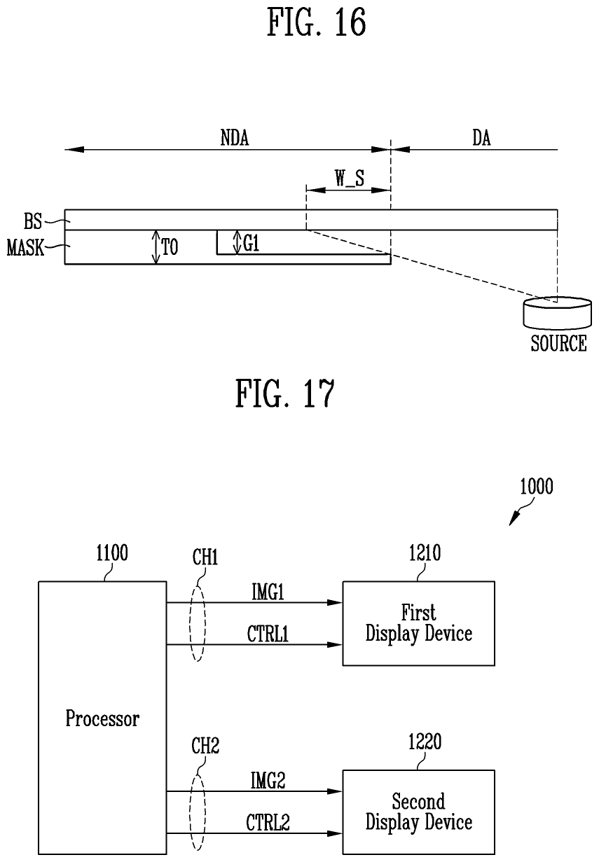

FIG. 17 is a diagram illustrating an embodiment of a display system.

Referring to FIG. 17, the display system 1000 may include a processor 1100 and one or more display devices 1210 and 1220.

The processor 1100 may perform various tasks and calculations. In embodiments, the processor 1100 may include an application processor, a graphic processor, a microprocessor, a central processing unit (CPU), and the like within the spirit and the scope of the disclosure. The processor 1100 may be connected to other components of the display system 1000 through a bus system and may control the other components.

In FIG. 17, the display system 1000 may include the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. The first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. The second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

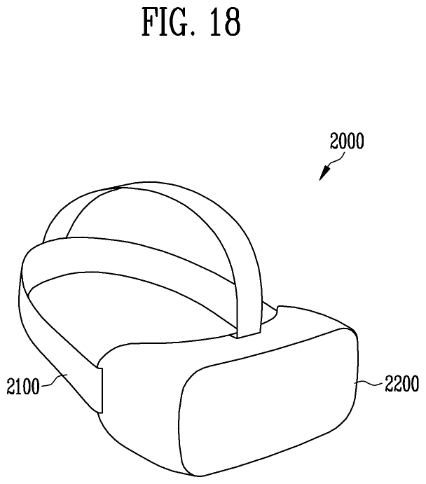

FIG. 18 is a perspective view illustrating an application example of the display system of FIG. 17.

Referring to FIG. 18, the display system 1000 of FIG. 17 may be applied to a head mounted display device 2000. The head mounted display device 2000 may be a wearable electronic device that may be worn on a user's head.

The head mounted display device 2000 may include a head mount band 2100 and a display device accommodation case 2200. The head mount band 2100 may be connected to the display device accommodation case 2200. The head mount band 2100 may include a horizontal band and/or a vertical band for fixing the head mounted display device 2000 to the user's head. The horizontal band may surround a side portion of the user's head, and the vertical band may surround an upper portion of the user's head. However, embodiments are not limited thereto. For example, the head mount band 2100 may be implemented in a glasses frame form, a helmet form, or the like within the spirit and the scope of the disclosure.

The display device accommodation case 2200 may accommodate the first and second display devices 1210 and 1220 of FIG. 17. The display device accommodation case 2200 may further accommodate the processor 1100 of FIG. 17.

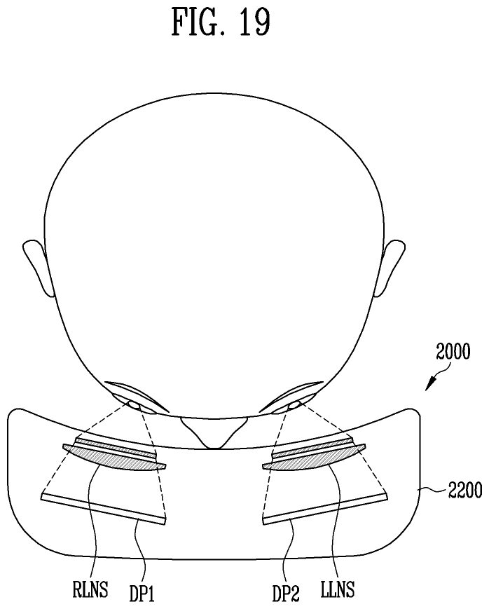

FIG. 19 is a diagram illustrating the head mounted display device worn by a user of FIG. 18.

Referring to FIG. 19, a head mounted display device 2000 (or the wearable electronic device) may include a display panel that emits light and a lens unit disposed on the display panel (or on an emission path of light). The display panel may include a first display panel DP1 of the first display device 1210 and a second display panel DP2 of the second display device 1220. The lens unit may further include one or more lenses LLNS and RLNS.

Within the display device accommodation case 2200, the right eye lens RLNS may be disposed between the first display panel DP1 and a user's right eye. Within the display device accommodation case 2200, the left eye lens LLNS may be disposed between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. Each display panel may output images, respectively corresponding to the sub-areas of the multi-channel lens, and the output images may pass through the respective corresponding sub-areas and may be viewed to the user.

Although embodiments and examples are described herein, other embodiments and modifications may be derived from the above description. Therefore, the spirit of the disclosure is not limited to such embodiments, and extends to the scope of the claims as set forth below, various obvious modifications, and equivalents.

What is claimed is:

1. A display device comprising:
display area and a non-display area;
a base layer; and
a light emitting element layer disposed on the base layer, wherein
the light emitting element layer comprises:
a first light emitting part including first organic patterns emitting light;
a charge generation layer disposed on the first light emitting part; and
a second light emitting part disposed on the charge generation layer,
the second light emitting part covers the charge generation layer in a plan view, and
the second light emitting part includes second organic patterns disposed in the display area, the second organic patterns emitting light and dummy patterns disposed in the non-display area.

2. The display device according to claim 1, wherein of a shortest path from the display area to an edge of the base layer, the charge generation layer expands by about 50 μm or more from an edge of the display area to the non-display area in a plan view.

3. The display device according to claim 2, wherein of the shortest path from the display area to the edge of the base layer, the second light emitting part expands by less than about 200 μm toward the edge of the base layer than the charge generation layer in a plan view.

4. The display device according to claim 1, wherein an average size of the dummy patterns is greater than or equal to an average size of the second organic patterns.

5. The display device according to claim 4, wherein the dummy patterns partially overlap each other and completely cover the charge generation layer in the non-display area in a plan view.

6. The display device according to claim 1, wherein the second organic patterns and the dummy patterns have a same stack structure.

7. The display device according to claim 1, wherein the dummy patterns and the second organic patterns have different stack structures.

8. The display device according to claim 7, wherein
the second organic patterns include a hole transport layer and a light emitting layer disposed on the hole transport layer, and
the dummy patterns include the hole transport layer or the light emitting layer.

9. The display device according to claim 1, further comprising:
a cathode electrode disposed on the light emitting element layer, wherein
the cathode electrode covers the second light emitting part, and
the charge generation layer and the cathode electrode are separated by the second light emitting part.

10. The display device according to claim 1, wherein
the light emitting element layer further comprises:
anode electrodes disposed on the base layer; and
a pixel defining layer covering the base layer and the anode electrode,
the pixel defining layer includes openings exposing the anode electrodes in the display area,
the openings are not disposed in the non-display area, and
the first light emitting part is disposed on the pixel defining layer and electrically connected to anode electrodes through the openings.

11. The display device according to claim 1, wherein organic patterns overlapping each other in a plan view among the first organic patterns and the second organic patterns emit light of a same color.

12. A display device comprising:
a display area and a non-display area;
a base layer; and
a light emitting element layer disposed on the base layer, wherein
the light emitting element layer comprises:
a first light emitting part emitting light;
a charge generation layer disposed on the first light emitting part; and
a second light emitting part disposed on the charge generation layer and emitting light,
a thickness of each of the first light emitting part, the charge generation layer, and the second light emitting part becomes thinner as a distance from the display area increases in the non-display area, and
each of the first light emitting part and the second light emitting part covers the charge generation layer in a plan view.

13. The display device according to claim 12, wherein of a shortest path from the display area to an edge of the base layer, the charge generation layer expands by about 50% or less from an edge of the display area than the first light emitting part or the second light emitting part in a plan view.

14. The display device according to claim 13, wherein of the shortest path from the display area to the edge of the base layer, each of the first light emitting part and the second light emitting part further expands in a range of about 100 μm to about 500 μm from the edge of the display area in a plan view.

15. The display device according to claim 12, wherein a decrease rate of a thickness of the charge generation layer according to a distance from an edge of the display area is greater than a decrease rate of a thickness of the first light emitting part.

16. The display device according to claim 12, wherein
each of the first light emitting part and the second light emitting part includes organic patterns emitting light, and
the organic patterns are disposed in the display area and are not disposed in the non-display area.

17. The display device according to claim 12, wherein
the charge generation layer includes a first charge generation layer and a second charge generation layer sequentially stacked between the first light emitting part and the second light emitting part, and
the second charge generation layer is disposed inside of the first charge generation layer.

18. The display device according to claim 17, wherein a decrease rate of a thickness of the second charge generation layer according to a distance from an edge of the display area is greater than a decrease rate of a thickness of the first charge generation layer.

19. The display device according to claim 12, further comprising:
a cathode electrode disposed on the light emitting element layer, wherein
the cathode electrode covers the second light emitting part, and
the charge generation layer and the cathode electrode are separated by the second light emitting part.

20. A wearable electronic device comprising:
a display panel emitting light; and
at least one lens disposed on the display panel, wherein
the display panel comprises:
a display area and a non-display area;
a base layer; and
a light emitting element layer disposed on the base layer,
the light emitting element layer comprises:
a first light emitting part including first organic patterns emitting light;
a charge generation layer disposed on the first light emitting part; and
a second light emitting part disposed on the charge generation layer,
the second light emitting part covers the charge generation layer in a plan view, and
the second light emitting part includes second organic patterns disposed in the display area and emitting light and dummy patterns disposed in the non-display area.
